(19) United States
(12) Patent Application Publication
(10) Pub. No.: US 2009/0191360 A1
(43) Pub. Date: Jul. 30, 2009

(54) STRIP CROSSBOW REDUCTION AND STRIP VIBRATION REDUCTION METHOD AND HOT DIP COATED STRIP MANUFACTURING METHOD USING THE STRIP STABILIZATION METHOD

(75) Inventors: Youji TERAMOTO, Hiroshima-shi (JP); Masami KAWANISHI, Hiroshima-shi (JP)

Correspondence Address: BIRCH STEWART KOLASCH & BIRCH, PO BOX 747, FALLS CHURCH, VA, 22040-0747, US

(73) Assignee: Mitsubishi-Hitachi Metals Machinery, Inc., Tokyo (JP)

(21) Appl. No.: 12/352,233

(22) Filed: Jan. 12, 2009

(30) Foreign Application Priority Data
Jan. 30, 2008 (JP) 2008-018506

(51) Int. Cl. C23C 14/22

(52) U.S. Cl. 427/595

(57) ABSTRACT

Provided is a strip crossbow reduction and vibration reduction method (strip stabilization method) including of controlling an exciting current to an electromagnet based on a distance to a strip being conveyed, the first distance being detected by a displacement sensor, and performing crossbow reduction and vibration reduction on the strip by means of an electromagnetic force of the electromagnet. The method is characterized in that the exciting current applied to the electromagnet is controlled based on the distance and a target position corresponding to the distance, and that the exciting current is applied to the electromagnet when the strip is present within detectable range of the displacement sensor whereas the exciting current is not applied to the electromagnet when the strip is not present within the detectable range of the displacement sensor.

### BACKGROUND OF THE INVENTION

1. Field of the Invention

The present invention relates to a strip crossbow reduction and strip vibration reduction method (strip stabilization method) for hot dip coating line, as well as to a method of manufacturing a hot dip coated strip using the strip stabilization method.

2. Description of the Related Art

Hot dip coating methods using zinc, aluminum and the like have been practically used for a long time. Particularly, there have been increasing demands for hot dip coated strip as rust-proof strip for automobiles, household electric appliances, and building materials. Moreover, along with the quality improvement of end products such as automobiles, household electric appliances, and building materials and the like, a quality improvement is now needed also for hot dip coated strip constituting these end products in terms of uniform coating amounts, surface defect control and so forth.

A recent typical method of coating molten metal on a continuously-coated strip is usually a gas wiping method, for example. In this gas wiping method, a strip continuously hot dipped in a coating pot of molten metal is pulled upward from the coating pot and then a wiping gas is impinged from a wiping nozzle onto the strip in this lifting process. In this way, the molten metal excessively coated on surfaces of the strip is removed so that a coating amount on the strip is adjusted as predetermined.

However, the strip processed in such gas wiping method may cause crossbow or vibration in a width direction due to the pulling action from the coating pot or tension owing thereto and the like. If a strip has crossbow or vibration, an interstice between the wiping nozzle and the strip is changed whereby the wiping gas is not impinged onto the surface of the strip evenly in the width direction or in a direction of conveyance. Accordingly, there has been a risk of an uneven coating amount on the strip.

To solve this, gas wiping equipment of this type is provided with a crossbow reduction and vibration reduction apparatus which is configured to reduce the crossbow of the strip being conveyed and to reduce the vibration thereof. This crossbow reduction and vibration reduction apparatus includes multiple sets of displacement sensors and electromagnets disposed closely to the wiping nozzle along the width direction of the strip. A distance to each region of the strip is constantly detected with the corresponding displacement sensors and exciting currents are applied to the corresponding electromagnets in response to the detected distances so that electromagnetic forces reduces the strip from across bow to flat shape and reduces the vibration thereof. The conventional strip crossbow reduction and vibration reduction method described above has been disclosed in Japanese Unexamined Patent Application Publication No. 2002-317259.

Here, a hot dip coating line that includes the above-described gas wiping equipment is provided with a line control apparatus configured to comprehensively control the entire line. This line control apparatus is set in advance with strip information including a thickness, width, tension, speed of conveyance, steel grade, and the like of the strip being conveyed. Moreover, by inputting this strip information from the line control apparatus respectively to devices constituting the line, the entire line is driven and controlled to manufacture a desired hot dip coated strip. Meanwhile, depending on the strip width according to the strip condition inputted from the line control apparatus, the crossbow reduction and vibration reduction apparatus of the hot dip coating line is configured to drive the sets of the displacement line sensors and the electromagnets located where the strip is present in front thereof, and to stop the sets of the displacement line sensors and the electromagnets located where the strip is absent in front thereof.

Incidentally, the hot dip coating line often continuously manufactures strips of multiple steel grades having different strip manufacturing information. In this case, a tail end of a precedent material located ahead is joined to a leading end of a following material of a different type that is located there behind, by means of welding or the like to form a welding point so as to process the materials collectively as a continuous strip.

However, passing timing of the welding point that is inputted from the line control apparatus may be different from the actual passing timing in some cases. Meanwhile, when the strip is conveyed, the conveying condition is not always constant so that the strip may meander in the width direction. As a result, the conventional crossbow reduction and vibration reduction method cannot accurately determine the actual edge portions of the strip being conveyed, and therefore may erroneously select the set of the displacement sensors and the electromagnets to be used.

Moreover, not only the thickness but also a meandering amount of the strip may be suddenly changed before and after the welding point. Accordingly, the displacement sensor configured to detect the distance to the strip may falsely detect the distance depending on a positional relationship with the edge portion of the strip. For this reason, in the conventional crossbow reduction and vibration reduction method, performing the control sometimes turns out to worsen the shape of the strip.

For such problems, as shown in Patent Document 1, there is a method of moving the displacement sensors and the electromagnets in the width direction of the strip in response to the change in the thickness or the meandering action of the strip. However, using this method causes a problem in responsiveness because the heavy materials are needed to be moved. In this way, there is generated a region on the edge portion of the strip where the electromagnetic force of the electromagnet does not apply. This causes a risk that the crossbow remains as a result of imperfect correction.

### SUMMARY OF THE INVENTION

The present invention has been made to solve the aforementioned problems. It is an object of the present invention to provide a strip crossbow reduction and vibration reduction method and a hot dip coated strip manufacturing method using the stabilization method, which are capable of reducing a crossbow of a strip being conveyed and for reducing vibration thereof even when a strip width or a meandering action of a strip is suddenly changed.

A strip crossbow reduction and vibration reduction method according to a first aspect of the present invention for solving the problems provides a method of controlling an exciting current applied to an electromagnet based on a first distance to a strip being conveyed, the first distance being detected by first detecting means, and performing crossbow reduction and vibration reduction on the strip by means of an electromagnetic force of the electromagnet, the method characterized in that: the exciting current applied to the electromagnet is controlled based on first distance and a predetermined first target position corresponding to the first distance; and that the exciting current is applied to the electromagnet when the strip is present within a detectable range of the first detecting means, whereas the exciting current is not applied to the electromagnet when the strip is not present within the detectable range of the first detecting means.

A strip crossbow reduction and vibration reduction method according to a second aspect of the present invention for solving the problems provides the strip crossbow reduction and vibration reduction method of the first aspect of the present invention, the method characterized in that: second distance to the strip is detected by second detecting means located on an outer side of the first detecting means in a width direction of the strip and also located in position not corresponding to the electromagnet; and that the first target position is corrected based on the second distance and a predetermined second target position corresponding to the second distance.

A strip crossbow reduction and vibration reduction method according to a third aspect of the present invention for solving the problems provides the strip crossbow reduction and vibration reduction method of the second aspect of the present invention, the method characterized in that the first target position is corrected when the strip is present within detectable range of the second detecting means, whereas the first target position is not corrected when the strip is not present within the detectable range of the second detecting means.

A strip crossbow reduction and vibration reduction method according to a fourth aspect of the present invention for solving the problems provides the strip crossbow reduction and vibration reduction method of the second aspect of the present invention, is the method characterized in that an amount of correction concerning the first target position is taken into consideration for an amount of correction obtained on an inner side of the first target position in the width direction of the strip.

A hot dip coated strip manufacturing method according to a fifth aspect of the present invention for solving the problems provides a hot dip coated strip manufacturing method that performs such control that a strip has a predetermined coating amount thereon, by impinging wiping gas onto the strip continuously pulled upward from a molten metal coating pot, so as to remove the molten metal excessively coated on surfaces of the strip, the method characterized in that the hot dip coated strip is manufactured by use of the strip crossbow reduction and vibration reduction method according to any of the first to fourth aspects of the present invention.

As described above, according to the strip crossbow reduction and vibration reduction method and the hot dip coated strip manufacturing method of the present invention, it is possible to reduce the strip crossbow accurately and to reduce vibration thereof, even when the strip width and the meandering action of the strip are suddenly changed. As a result, it is possible to achieve a uniform coating amount onto the strip in the width direction.

### BRIEF DESCRIPTION OF THE DRAWINGS

FIG. 1 is a schematic diagram of gas wiping equipment including a crossbow reduction and vibration reduction apparatus according to the present invention.

FIG. 2 is a front view of a crossbow reduction and vibration reduction apparatus according to a first embodiment of the present invention.

FIG. 3 is a front view of a crossbow reduction and vibration reduction apparatus according to a second embodiment of the present invention.

FIG. 4 is a block diagram of a control unit.

FIG. 5 is a view showing how an edge portion of a strip is subjected to crossbow reduction and vibration reduction.

### DETAILED DESCRIPTION OF THE INVENTION

Now, a strip crossbow reduction and vibration reduction method and a hot dip coated strip manufacturing method according to the present invention will be described below in detail with reference to the accompanying drawings. In the embodiments to be described below, constituents having similar structures and functions will be denoted by the same reference numerals and duplicated explanations will be omitted therein.

### First Embodiment

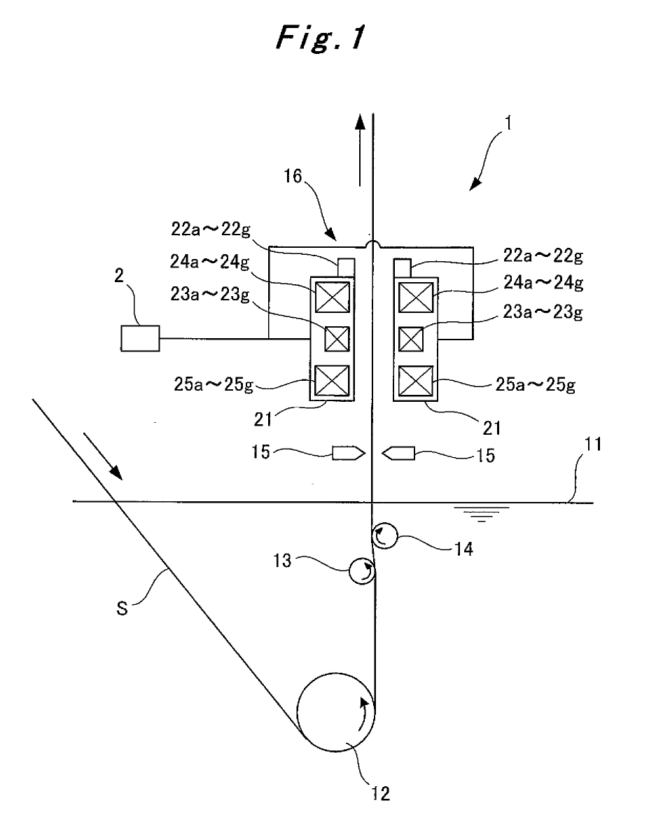

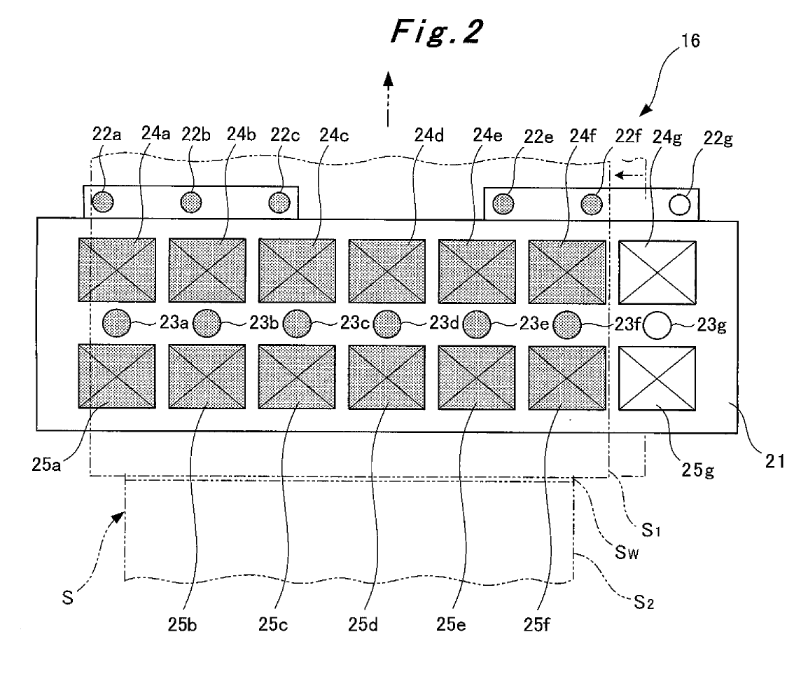

FIG. 1 is the schematic diagram of gas wiping equipment including a crossbow reduction and vibration reduction apparatus according to the present invention, and FIG. 2 is a front view of a crossbow reduction and vibration reduction apparatus according to a first embodiment of the present invention.

Gas wiping equipment 1 shown in FIG. 1 is provided in an unillustrated hot dip coating line, and is configured to coat molten metal such as zinc, aluminum or the like on a strip S that is continuously conveyed. Here, as shown in FIG. 2, the strip S for manufacturing the hot dip coated strip includes a preceding material S1 and a following material S2, and has a welding point Sw that connects a tail end of the preceding material S1 to a leading end of the following material S2 by welding.

As shown in FIG. 1, a coating pot 11 for pooling molted metal maintained at a high temperature is disposed below the gas wiping equipment 1. Inside the coating pot 11, a sink roll 12 for winding the dipped strip S and directing the dipped strip S upward, and a pair of support rolls 13 and 14 disposed so as to sandwich the strip S conveyed from this sink roll 12 are rotatably supported.

A pair of wiping nozzles 15 are opposed to each other above a pot surface of the coating pot 11 so as to sandwich the strip S along the strip thickness direction. These wiping nozzles 15 are configured to remove the excessive molten metal coated on the surfaces of the strip S by impinging wiping gas onto the strip S coated with the molten metal, and thereby to adjust to a predetermined coating amount of the molten metal on the strip S. Moreover, a crossbow reduction and vibration reduction apparatus 16 is provided above the wiping nozzle 15 for reducing a crossbow of the strip S and for reducing the vibration thereof.

As shown in FIGS. 1 and 2, the crossbow reduction and vibration reduction apparatus 16 includes a pair of mount tables 21 which are opposed to each other so as to sandwich the strip S along the strip thickness direction. Moreover, displacement sensors (first detecting means) 23a to 23g, electromagnets 24a to 24g, and electromagnets 25a to 25g are provided on inner surfaces respectively of the opposed mount tables 21 so as to be opposed to one another and sandwich the strip S in the strip thickness direction.

Each element of the displacement sensors 23a to 23g, and the electromagnets 24a to 24g as well as 25a to 25g is disposed at a predetermined interval in the width direction of the strip S, and the displacement sensors 23a to 23g are provided at an intermediate portion between the electromagnets 24a to 24g and the electromagnets 25a to 25g in the conveying direction of the strip S. Specifically, the displacement sensors 23a to 23g and the respective electromagnets 24a to 24g as well as the respective electromagnets 25a to 25g disposed respectively above and below the displacement sensors 23a to 23g each constitute one set, and more than one such set (seven sets in the drawing) are disposed on the mount tables 21 in the width direction of the strip S.

Each of the displacement sensors 23a to 23g is, for example, an eddy-current sensor configured to detect a distance (a first distance) to the corresponding region of the strip S Meanwhile, the electromagnets 24a to 24g and the electromagnets 25a to 25g are configured to reduce the crossbow of the strip S and to reduce the vibration thereof by using electromagnetic forces. Moreover, the displacement sensors 23a to 23g constantly detect the distances to the respective regions of the strip S facing the displacement sensors 23a to 23g, and exciting currents are applied to the electromagnets 24a to 24q and 25a to 25g according to the respective detected distances. The electromagnetic forces reduce the crossbow of the strip S and a passing point of the strip S between the wiping nozzles 15, and reduce the vibration thereof.

Meanwhile, strip detection sensors 22a to 22g are opposed to one another on an outside of upper parts of the mount tables 21 so as to sandwich the strip S in the strip thickness direction. The strip detection sensors 22a to 22g are disposed at predetermined intervals in the width direction of the strip S so as to face an edge portion of the strip S being conveyed. Each of the strip detection sensors 22a to 22c and 22e to 22g is disposed in a way to correspond to the corresponding position of each of a pair of three sets of the displacement sensors 23a to 23c and 23e to 23g, the electromagnets 24a to 24c and 24e to 24g, and the electromagnets 25a to 25c and 25e to 25g, which are disposed on outer sides of the mount tables 21 in the width direction of the strip S. The strip detection sensors 22a to 22c and 22e to 22g are each disposed in a position off the center of corresponding one of the displacement sensors 23a to 23c and 23e to 23g in the width direction of the strip S.

The strip detection sensors 22a to 22g are, for example, light projecting-receiving sensors which are configured to detect presence of the strip S being conveyed so as to judge whether or not there is the strip S in detectable ranges of the respective displacement sensors 23a to 23g. Moreover, when the strip S is detected by the strip detection sensors 22a to 22g, the displacement sensors 23a to 23g and the electromagnets 24a to 24g and 25a to 25g corresponding to the respective displacement sensors 23a to 23g that have detected the strip S, are driven. In contrast, when the strip S is not detected by the strip detection sensors 22a to 22g, the displacement sensors 23a to 23g and the electromagnets 24a to 24g and 25a to 25g corresponding to the respective displacement sensors 23a to 23g that have not detected the strip S, are stopped being driven.

Here, the hot dip coating line includes a line control apparatus 2 configured to comprehensively control the entire line. Moreover, the line control apparatus 2 is set in advance with strip information including strip thicknesses, strip widths, tension, speeds of conveyance, steel grades, and the like of the preceding material S1 and the following material S2 of the strip S being conveyed. The entire line is driven and controlled to manufacture a desired hot dip coated strip by inputting this strip information into the devices constituting the line and into the crossbow reduction and vibration reduction apparatus 16 of the gas wiping equipment 1.

Accordingly, by applying the above-described configuration, the strip S continuously dipped in the coating pot 11 is directed almost vertically upward by the sink roll 12 and is pulled up above the pot surface of the coating pot 11 through the support rolls 13 and 14. Then, when the pulled strip S is conveyed to the space between the wiping nozzles 15, the wiping gas is impinged from the wiping nozzles 15 onto this strip S. In this way, an excessive amount of the molten metal coated on the surfaces of the strip S is taken off so that the surfaces of the strip S are coated with a predetermined thickness.

Subsequently, the coated strip S is conveyed to the crossbow reduction and vibration reduction apparatus 16. In this event, when a meandering action (meandering leftward in the drawing) of the strip S occurs as shown in FIG. 2, a judgment is made that the strip S is present within the detectable ranges of the displacement sensors 23a to 23f as the strip S is detected by the strip detection sensors 22a to 22f. Meanwhile, a judgment is made that the strip S is not present within the detectable range of the displacement sensor 23g as the strip S is not detected by the strip detection sensor 22g. In addition, the control of the electromagnets 24a to 24f and 25a to 25f corresponding to the strip detection sensors 22a to 22f is permitted while the control of the electromagnets 24g and 25g corresponding to the strip detection sensor 22g is not permitted.

Thereafter, the displacement sensors 23a to 23f detects the distances to the respective regions of the strip S facing the displacement sensors 23a to 23f, and the thus detected distances to the respective regions of the strip S are compared with a target position (a first target position) inputted by the line control apparatus 2. Subsequently, the exciting currents to be applied to the respective electromagnets 24a to 24f and 25a to 25f are adjusted so as to allow the respective distances to meet the target position. Thereby, the resultant electromagnetic forces reduce the crossbow of the strip S and the passing point of the strip S between the wiping nozzles 15, and reduce the vibration thereof.

Therefore, according to the crossbow reduction and vibration reduction method of the present invention, the presence of the strip S being conveyed is detected by use of the strip detection sensors 22a to 22g and thereby it is judged whether or not the strip S is present within the detectable ranges of the displacement sensors 23a to 23g corresponding to the strip detection sensors 22a to 22g. In this way, it is possible to make the most suitable selection of the sets of the displacement sensors 23a to 23g and the electromagnets 24a to 24g and 25a to 25g to be used. As a consequence, even when the strip width is changed from the strip width of the preceding material S1 to that of the following material S2 or when the meandering action is suddenly changed at the passing timing of the welding point Sw of the strip S, it is possible to reduce the crossbow of the strip S accurately and to reduce the vibration thereof at the same time.

### Second Embodiment

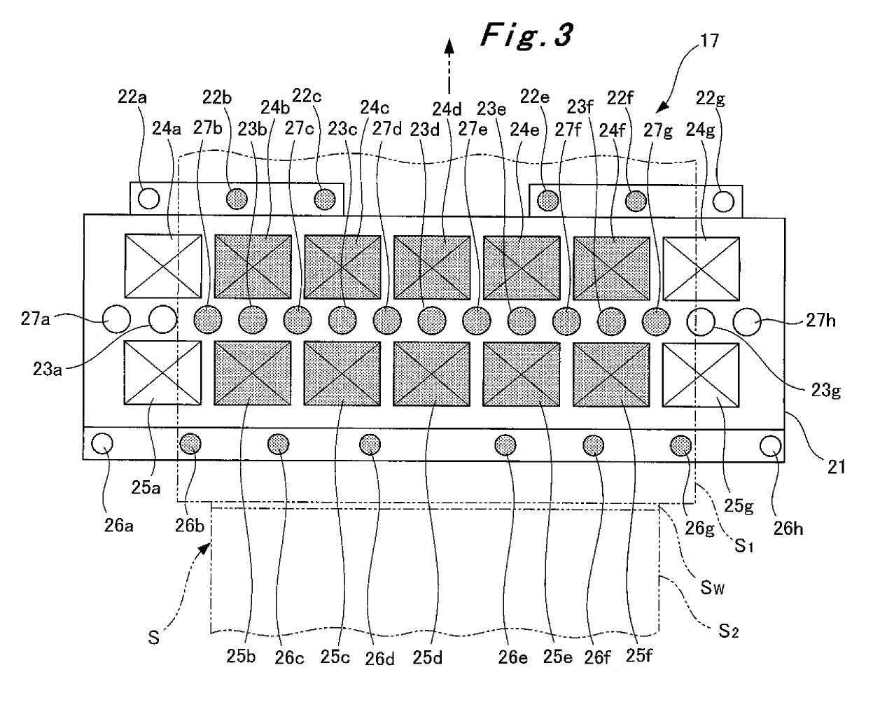

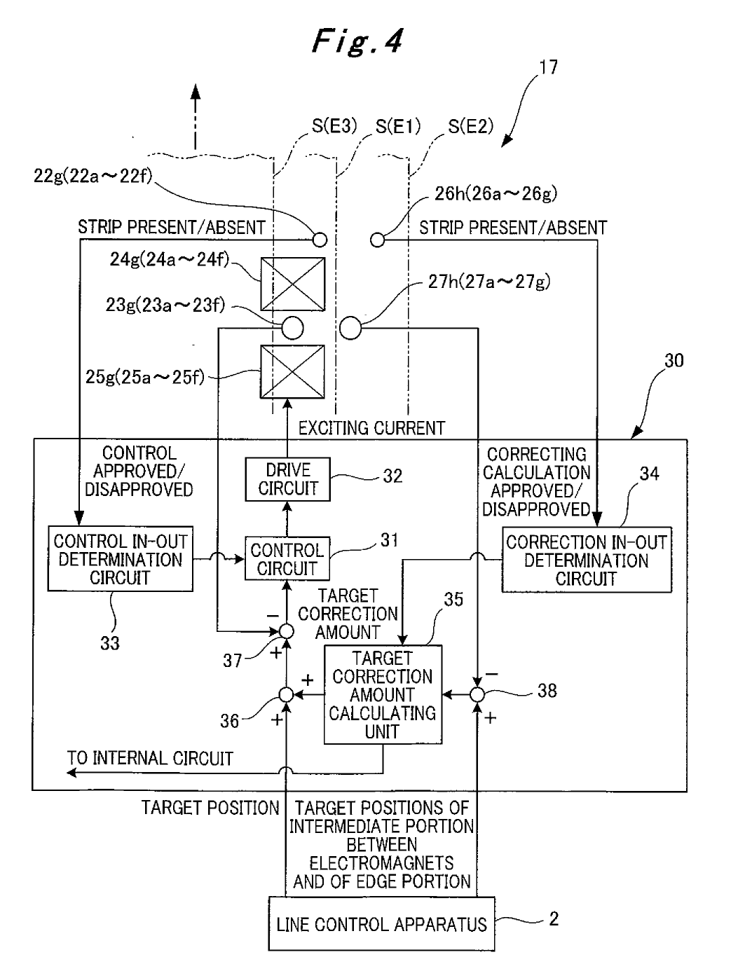

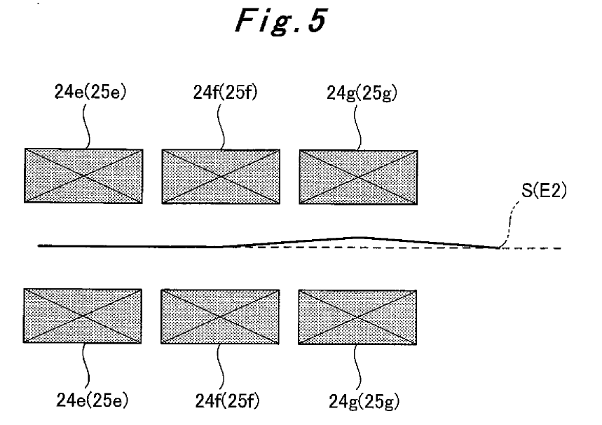

FIG. 3 is a front view of a crossbow reduction and vibration reduction apparatus according to a second embodiment of the present invention. FIG. 4 is a block diagram of a control unit. FIG. 5 is a view showing how an edge portion of a strip is subjected to crossbow reduction and vibration reduction.

As shown in FIG. 3, the gas wiping equipment 1 is provided with a crossbow reduction and vibration reduction apparatus 17. This crossbow reduction and vibration reduction apparatus 17 includes strip detection sensors 26a to 26h and displacement sensors (second detecting means) 27a to 27h, in addition to the mount tables 21, the strip detection sensors 22a to 22g, the displacement sensors 23a to 23g, and the electromagnets 24a to 24g and 25a to 25g described above.

The strip detection sensors 26a to 26h and the displacement sensors 27a to 27h are similar sensors to the strip detection sensors 22a to 22g and the displacement sensors 23a to 23g, respectively, and are both are provided on the inner surfaces of the opposed mount tables 21 so as to be opposed to one another and sandwich the strip S in the strip thickness direction.

The displacement sensors 27a to 27h are disposed alternately with the displacement sensors 23a to 23g in the width direction of the strip S. In addition, the displacement sensors 27a to 27h are each located at an intermediate portion respectively between the adjacent displacement sensors 23a to 23g along the width direction of the strip S, and also located at an intermediate portion between the electromagnets 23a to 24g and the electromagnets 25a to 25g in the conveying direction of the trip S. That is, the displacement sensors 27a to 27h are configured to detect distances (second distances) to the intermediate portion and the edge portion of the strip S where the electromagnetic forces of the electromagnets 24a to 24g and 25a to 25g are not effective. Meanwhile, each of the strip detection sensors 26a to 26h is disposed below the mount tables 21 at a predetermined interval in the width direction of the strip S, and is disposed in a position off the center of corresponding one of the displacement sensors 27a to 27h in the width direction of the strip S.

Moreover, the displacement sensors 27a to 27h constantly detect the distances to the intermediate portion and the edge portions of the strip S that face the displacement sensors 27a to 27h. Then, in accordance with the distances detected by the displacement sensors 27a to 27h, the displacement sensors 23a to 23g disposed on the inside in the width direction of the strip S correct the target positions corresponding to the detected distances. Subsequently, the exciting currents are applied to the electromagnets 24a to 24g and 25a to 25g according to the corrected target positions. In this way, the electromagnetic forces reduce the crossbow of the strip S and the passing point of the strip S between the wiping nozzles 15, and reduce the vibration thereof.

Moreover, when the strip S is detected by the strip detection sensors 26a to 26h, the displacement sensors 27a to 27h corresponding to the respective displacement sensors 26a to 26h that have detected the strip S, are driven. In contrast, when the strip S is not detected by the strip detection sensors 26a to 26h, the displacement sensors 27a to 27h corresponding to the respective displacement sensors 26a to 26h that have not detected the strip S, are stopped being driven.

As shown in FIG. 4, the crossbow reduction and vibration reduction apparatus 17 is connected to the line control apparatus 2 through a control unit 30. This control unit 30 incorporates a control circuit 31, a drive circuit 32, a control on-off determination circuit 33, a correction on-off determination circuit 34, a target correction amount calculating unit 35, an adder, 36, and subtracters 37 and 38. Here, the control unit 30 shown in FIG. 4 representatively illustrates a state of connection among the strip detection sensors 22g and 26h, the displacement sensors 23g and 27h, and the electromagnets 24g and 25g, which are disposed on outer portions of the strip S in the width direction.

In the control unit 30, the distances to the respective regions of the strip S detected by the displacement sensors 23a to 23g are inputted into the subtracter 37. Meanwhile, the target position of the strip S is inputted from the line control apparatus 2 into the subtracter 37 through the adder 36. Then, differences between the distances to the respective regions of the strip S detected by the displacement sensors 23a to 23g and the target position inputted from the line control device 2 are calculated. The values of the differences thus calculated are then inputted from the subtracter 37 into the drive circuit 32 through the control circuit 31. Subsequently, the exciting currents corresponding to the values of the calculated differences are applied from the drive circuit 32 to the electromagnets 24a to 24g and 25a to 25g, whereby the electromagnets 24a to 24g and 25a to 25g generate the electromagnetic forces that act on the strip S, based on the magnitudes of the exciting currents.

At this time, when the strip S is detected by the strip detection sensors 22a to 22g, strip presence signals are inputted into the control on-off determination circuit 33. In this way, the control on-off determination circuit 33 approves the control by the control circuit 31 and outputs a control approval signal to the control circuit 31. As a result, the control circuit 31 is able to output the difference values calculated by the subtracter 37 to the drive circuit 32, which in turn allows the electromagnets 24a to 24g and 25a to 25g to be driven.

In contrast, when the strip S is not detected by the strip detection sensors 22a to 22g, strip absence signals are inputted into the control on-off determination circuit 33. In this way, the control on-off determination circuit 33 disapproves the control by the control circuit 31 and outputs a control disapproval signal to the output circuit 31. As a result, the control by the control circuit 31 is disabled and the drive circuit 32 is stopped, which in turn stops the electromagnets 24a to 24g and 25a to 25g as well.

In addition, the distances to the intermediate portion of and to the edge portions of the strip S that are detected by the displacement sensors 27a to 27h are inputted into the subtracter 38. On the other hand, a target position of the intermediate portion of and a target position of the edge portions (second target positions) of the strip S are inputted from the line control apparatus 2 into the subtracter 38 through. Then, the subtracter 38 calculates the differences between the distances to the intermediate portion and to the edge portions of the strip S detected by the displacement sensors 27a to 27h and the target position of the respective intermediate portion as well as the respective target position of the edge portions inputted from the line control device 2. The difference values thus calculated are inputted from the subtracter 38 into the target correction amount calculating unit 35. Based on the inputted difference values, the target correction amount calculating unit 35 calculates the target correction amount for allowing the edge portion of the strip S to reach the target position of the edge portion. The target correction amount thus calculated is then inputted from the target correction amount calculating unit 35 into the adder 36. Subsequently, the adder 36 calculates a sum of the target position inputted from the line control apparatus 2 and the target correction amount calculated by the target correction amount calculating unit 35.

At this time, if the strip S is detected by the strip detection sensors 26a to 26h, strip presence signals are inputted into the correction on-off determination circuit 34. In this way, the correction on-off determination circuit 34 approves the correcting calculation by the target correction amount calculating unit 35, and outputs a correcting calculation approval signal to the target correction amount calculating unit 35. As a result, the target correction amount calculating unit 35 is able to output the calculated target correction amount to the adder 36 which in turn drives the electromagnets 24a to 24g and 25a to 25g.

Note that, it is also possible to input the target correction amount calculated by the target correction amount calculating unit 35 into another target correction amount calculating unit 35 disposed further inside in the width direction of the strip S and to add the target correction amount to another target correction amount calculated by the target correction amount calculating unit 35 located inside.

In contrast, when the strip S is not detected by the strip detection sensors 26a to 26h, strip absence signals are inputted into the correction on-off determination circuit 34. In this way, the correction on-off determination circuit 34 disapproves the correcting calculation by the target correction amount calculating unit 35, and outputs a correcting calculation disapproval signal to the target correction amount calculating unit 35. As a result, the correcting calculation by the target correction amount calculating unit 35 is disabled and the target position inputted into the adder 36 remains unchanged.

Here, descriptions will be given for the process operations in the control unit 30 at the time of conveying the strip S to the crossbow reduction and vibration reduction apparatus 17. Note that, in the following descriptions, the process operations using a single set of the strip detection sensor 22g, the displacement sensor 23g, the electromagnets 24q and 25g, and the strip detection sensor 26h as well as the displacement sensor 27h which correspond thereto will be explained below as a typical example.

Firstly, as shown in FIG. 4, a description will be given below for a case where the edge portion of the strip S being conveyed is located in a position E1.

Since the strip S is detected by the strip detection sensor 22g, a judgment is made that the strip S is present within the detectable range of the displacement sensor 23g corresponding to the strip detection sensor 22g. In contrast, since the strip S is not detected by the strip detection sensor 26h, a judgment is made that the strip S is not present within the detectable range of the displacement sensor 27h corresponding the strip detection sensor 26h. In this way, it is confirmed that the edge portion of the strip S is located in the position E1 between the displacement sensors 23g and 27h.

Then, when the strip presence signal is inputted from the strip detection sensor 22g into the control on-off determination circuit 33, the control on-off determination circuit 33 approves the control by the control circuit 31, and the control approval signal is inputted into the control circuit 31. In addition, the distance to the region of the strip S detected by the displacement sensor 23g is inputted into the subtracter 37. Moreover, the target position of the strip S is inputted from the line control apparatus 2 to the subtracter 37 through the adder 36. At this time, since the strip S is not detected by the strip detection sensor 26h, the correcting calculation by the target correction amount calculating unit 35 is disabled so that the target correction amount is not inputted into the adder 36.

Accordingly, the subtracter 37 calculates the difference between the distance to the region of the strip S that is detected by the displacement sensor 23g and the target position inputted by the line control apparatus 2, and the difference value thus calculated is inputted into the control circuit 31. Subsequently, the control circuit 31 inputs the difference value calculated by the subtracter 37 into the drive circuit 32, and the drive circuit 32 applies the exciting currents to the electromagnets 24q and 25g based on the calculated difference values. Consequently, the electromagnets 24g and 25g generate the certain electromagnetic forces on the strip S.

Next, as shown in FIG. 4, a case where the edge portion of the strip S being conveyed is located in a position E2 will be described.

With the strip S detected by the strip detection sensor 22g, a judgment is made that the strip S is present in the detectable range of the displacement sensor 23g corresponding to the strip detection sensor 22q. At the same time, with the strip S detected by the strip detection sensor 26h, a judgment is made that the strip S is present in the detectable range of the displacement sensor 27h corresponding the strip detection sensor 26h. In this way, it is confirmed that the edge portion of the strip S is located in the position E2 in an outer side of the displacement sensor 27h in the width direction of the strip S.

Then, since the strip presence signal is inputted from the strip detection sensor 22q into the control on-off determination circuit 33, the control on-off determination circuit 33 approves the control by the control circuit 31 and the control approval signal is inputted into the control circuit 31. In addition, the distance to the region of the strip S detected by the displacement sensor 23g is inputted into the subtracter 37. Moreover, the target position of the strip S is inputted from the line control apparatus 2 into the adder 36.

In contrast, when the strip presence signal is inputted from the strip detection sensor 26g into the correction on-off determination circuit 34, the correction on-off determination circuit 34 approves the correcting calculation by the target correction amount calculating unit 35. Hence the correcting calculation approval signal is inputted into the target correction amount calculating unit 35. At this time, the subtracter 38 calculates the difference between the distance to the edge portion of the strip S detected by the displacement sensor 27h and the target position of the edge portion inputted from the line control apparatus 2, and the difference values thus calculated is inputted from the subtracter 38 into the target correction amount calculating unit 35. Subsequently, based on the inputted difference value, the target correction amount calculating unit 35 calculates the target correction amount for allowing the edge portion of the strip S to reach the target position of the edge portion, and then outputs the target correction amount to the adder 36.

In this way, after the adder 36 calculates the sum of the target correction amount calculated by the target correction amount calculating unit 35 and the target position inputted from the line control apparatus 2, the subtracter 37 calculates the difference between the sum value thus calculated and the distance to the region of the strip S detected by the displacement sensor 23g, and then the difference value thus calculated is inputted into the control circuit 31. Subsequently, the control circuit 31 inputs the difference value calculated by the subtracter 37 into the drive circuit 32 and the exciting currents each corresponding to the calculated difference value are applied from the drive circuit 32 to the electromagnets 24g and 25g, whereby the electromagnets 24g and 25g generate the given electromagnetic forces on the strip S.

As a result, as shown in FIG. 5, the target correction amount is obtained from the difference between the distance to the edge portion of the strip S detected by the displacement sensor 27h and the target position of the edge portion, and this target correction amount is taken into consideration for the target position set up by the set of the strip detection sensor 22g, the displacement sensor 23g, and the electromagnets 24g and 25g driven inside. In this way, it is possible to correct the edge portion to the target position without rendering the edge portion of the strip S facing the electromagnets. Hence it is possible to uniformize, in other words, to flatten the shape of the whole strip S.

Next, as shown in FIG. 4, a case where the edge portion of the strip S being conveyed is located in a position E3 will be described.

When the strip S is not detected by the strip detection sensor 22g, a judgment is made that the strip S is not present within the detectable range of the displacement sensor 23g corresponding to the strip detection sensor 22g. In this way, it is confirmed that the edge portion of the strip S is located in the position E3 which is provided in an inner side of the displacement sensor 23g in the width direction of the strip S.

Then, with the strip absence signal having been inputted from the strip detection sensor 22g into the control in-out judgment unit 33, the control in-out determination circuit 33 disapproves the control by the control circuit 31, and the control disapproval signal is inputted to the control circuit 31. Consequently, the electromagnets 24g and the 25g are stopped being driven.

This embodiment is configured to output the target position, the target position of the intermediate portion, and the target position of the edge portion, to the control unit 30 from the line control apparatus 2. However, it should be noted that it is also possible to provide the crossbow reduction and vibration reduction apparatus 17 with a terminal device so as to output the target position, the target position of the intermediate portion, and the target position of the edge portion to the control unit 30 from this terminal device.

In the crossbow reduction and vibration reduction method of the present invention, the displacement sensors 27a to 27h are configured to detect the distances to the intermediate portion and the edge portions of the strip S where the electromagnetic forces of the electromagnets 24a to 24g and 25a to 25g are not effective. Moreover, the target position set up inside are corrected by using the distances thus detected. Therefore, by the crossbow reduction and vibration reduction method of the present invention, it is possible make a suitable selection of the sets of the displacement sensors 23a to 23g and the electromagnets 24a to 24g and 25a to 25g to be used for the strip S being conveyed. Thereby, even when the strip width is changed from the width of the preceding material S1 to the width of the following material S2 or the meandering action is suddenly changed at the passing timing of the welding point Sw of the strip S, it is possible to reduce the crossbow of the strip S precisely in a wider range in the width direction thereof, and to reduce the vibration at the same time. As a consequence, it is possible to uniformize the coating amount on the strip S in the width direction and thereby to manufacture a high-quality hot dip coated strip.

Moreover, since it is possible to deal with the sudden change in the strip width or the change in the meandering action after the passage of the welding point Sw of the strip S, it is not necessary to provide movement mechanisms for moving the strip detection sensors 22a to 22g and 26a to 26h, the displacement sensors 23a to 23g and 27a to 27h, and the electromagnets 24a to 24g and 25a to 25g. Hence it is possible to downsize the equipment as a whole.

1. A strip crossbow reduction and vibration reduction method comprising:
controlling an exciting current applied to an electromagnet based on a first distance to a strip being conveyed, the first distance being detected by first detecting means; and
performing crossbow reduction and vibration reduction on the strip by means of an electromagnetic force of the electromagnet, wherein
the exciting current applied to the electromagnet is controlled based on the first distance and a predetermined first target position corresponding to the first distance, and
that the exciting current is applied to the electromagnet when the strip is present within a detectable range of the first detecting means, whereas the exciting current is not applied to the electromagnet when the strip is not present within the detectable range of the first detecting means.

2. The strip crossbow reduction and vibration reduction method according to claim 1, wherein
a second distance to the strip is detected by second detecting means located on an outer side of the first detecting means in a width direction of the strip and also located in position not corresponding to the electromagnet, and
that the first target position is corrected based on the second distance and a predetermined second target position corresponding to the second distance.

3. The strip crossbow reduction and vibration reduction method according to claim 2, wherein the first target position is corrected when the strip is present within detectable range of the second detecting means whereas the first target position is not corrected when the strip is not present within the detectable range of the second detecting means.

4. The strip crossbow reduction and vibration reduction method according to claim 2, wherein an amount of correction concerning the first target position is taken into consideration for an amount of correction obtained on an inner side of the first target position in the width direction of the strip.

5. A hot dip coated strip manufacturing method that performs such control that a strip has a predetermined coating amount thereon, by impinging wiping gas onto the strip continuously pulled upward from a molten metal coating pot, so as to remove the molten metal excessively coated on surfaces of the strip, wherein the hot dip coated strip is manufactured by use of the strip crossbow reduction and vibration reduction method according to claim 1.

6. A hot dip coated strip manufacturing method that performs such control that a strip has a predetermined coating amount thereon, by impinging wiping gas onto the strip continuously pulled upward from a molten metal coating pot, so as to remove the molten metal excessively coated on surfaces of the strip, wherein the hot dip coated strip is manufactured by use of the strip crossbow reduction and vibration reduction method according to claim 2.

7. A hot dip coated strip manufacturing method that performs such control that a strip has a predetermined coating amount thereon, by impinging wiping gas onto the strip continuously pulled upward from a molten metal coating pot, so as to remove the molten metal excessively coated on surfaces of the strip, wherein the hot dip coated strip is manufactured by use of the strip crossbow reduction and vibration reduction method according to claim 3.

8. A hot dip coated strip manufacturing method that performs such control that a strip has a predetermined coating amount thereon, by impinging wiping gas onto the strip continuously pulled upward from a molten metal coating pot, so as to remove the molten metal excessively coated on surfaces of the strip, wherein the hot dip coated strip is manufactured by use of the strip crossbow reduction and vibration reduction method according to claim 4.
